(19) United States
(12) Patent Application Publication
(10) Pub. No.: US 2026/0031523 A1
(43) Pub. Date: Jan. 29, 2026

(54) LOW BAND ANTENNA ASSEMBLY FOR A ROLLABLE DISPLAY COMMUNICATION DEVICE

(71) Applicant: MOTOROLA MOBILITY LLC, WILMINGTON, DE (US)

(72) Inventors: JUNSHENG ZHAO, VERNON HILLS, IL (US); XUYUAN PAN, CHICAGO, IL (US); MD FAISAL ABEDIN, LAKE BLUFF, IL (US); MOHAMMED ABDUL-GAFFOOR, PALATINE, IL (US)

(21) Appl. No.: 18/782,736

(22) Filed: Jul. 24, 2024

(51) Int. Cl. H01Q 1/24; H01Q 9/04; H05K 5/02

(52) U.S. Cl. CPC H01Q 1/243; H01Q 9/0421; H05K 5/0217

(57) ABSTRACT

An antenna assembly, communication device and method provide incorporating low band radio frequency communication transmission and reception antenna elements within a narrow and small spatial footprint. The antenna assembly has a first planar antenna element that includes a radiating end portion extending in a first direction and electrically connectable to an antenna feed and a radiating arm extending in an opposite second direction opposite. The antenna assembly has a second planar antenna element that includes a coupling arm extending in the second direction parallel to and spaced by a slit from the radiating arm with a coupling end portion extending in the second direction from the coupling arm and electrically connectable to an antenna ground. The communication includes a support structure having a rectangular prismatic shape with a front side and back side that are larger than left, right, top, and bottom sides. Antenna assembly(ies) are positioned on narrow edge(s).

### BACKGROUND

### 1. Technical Field

The present disclosure relates generally to mobile communication devices having a display for presenting a user interface, and more particularly to mobile communication devices having a rollable display.

### 2. Description of the Related Art

Mobile communication devices such as smartphones provide a large amount of functionality in a small form factor. The small size enables mobility but limits available space for antennas. Antennas are needed to support communications in multiple radio frequency (RF) communication bands such as: (i) low band (LB) (e.g., ≤1 GHz); (ii) medium band (MB) (e.g., 1.7 to 2.2 GHz); (iii) high band (HB) (e.g., 2.3 to 2.7 GHz); (iv) ultra-high band (UHB) (e.g., 3.3 to 5 GHz); and (v) millimeter wave (mmWave) band (e.g., ≥24 GHz). A plurality of antennas that are placed at spaced apart positions are required to provide support for spatial diversity, multiple input multiple output (MIMO) operation, and concurrent communications, including for carrier aggregation and transmit diversity. The required size of antenna elements for effective transmission and reception is related to a wavelength range of particular communication bands. Needing to be relatively larger, antenna elements for lower bands are difficult to incorporate into the small form factor. With introduction of a rollable form factor, available spaces for low band antennas is limited to the non-rolling edges (e.g., lateral sides) of the communication device with the rolling edges (e.g., top and bottom sides) blocked by rolling display components. The non-rolling edges also tend to be held by a user, creating additional antenna/transmission blocking issues.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 presents a simplified functional block diagram of an electronic device in which the features of the present disclosure are advantageously implemented to incorporate an antenna assembly having low band radio frequency (RF) communications capabilities into narrow edges of a small form factor, according to one or more embodiments;

FIG. 2 illustrates the example antenna assembly of FIG. 1, according to one or more embodiments;

FIG. 3 illustrates an example antenna assembly for low band/ultra-low band (LB/ULB) communications that includes a radiating end portion having a short arm dimensioned for one or more of medium band (MB), high band (HB) and ultra-high band (UHB) communications, according to one or more embodiments;

FIG. 4 illustrates the example antenna assembly of FIG. 3 with further grounding of the short arm to improve LB tuning, according to one or more embodiments;

FIG. 5 illustrates a three-dimensional view of an example communication device including the antenna assembly of FIG. 2, according to one or more embodiments;

FIG. 6 illustrates an example antenna assembly having a parallel planar arrangement of antenna elements, according to one or more embodiments;

FIG. 7 illustrates a cutaway front right side of an example communication device having the antenna assembly of FIG. 5, according to one or more embodiments;

FIG. 8 illustrates a front view of a communication device with a rolling display surrounded by a thin edge portion that can enclose any of the antenna assemblies of FIGS. 2, 3 and 4, according to one or more embodiments;

FIG. 9 illustrates a front view of a communication device with a rolling display surrounded by a thick edge portion that can enclose the antenna assembly of FIG. 5, according to one or more embodiments;

FIG. 10 illustrates a front view of the example communication device being gripped on left and right sides, according to one or more embodiments;

FIG. 11 illustrates a back view of the example communication device being gripped on left and right sides, according to one or more embodiments;

FIG. 12 presents a three-dimensional view of the communication device with the antenna assembly (FIG. 2) for simulated antenna performance comparison, according to one or more embodiments;

FIG. 13 illustrates a three-dimensional view of a more conventional communication device having an antenna assembly that only has first planar antenna elements in line with a stub second planar antenna assembly having no coupling arm, according to one or more embodiments;

FIG. 14 depicts graphical plots of voltage standing wave ratio (VSWR) as a function of frequency respectively for the antenna assembly of FIG. 12 and the more conventional antenna assembly of FIG. 13, according to one or more embodiments; and

FIG. 15 is a flow diagram presenting a method for making a communication device having an antenna assembly configured for low band (LB) communication and positioned on a narrow side of a support structure, according to one or more embodiments.

### DETAILED DESCRIPTION

According to one aspect of the present disclosure, an antenna assembly supports low band radio frequency (RF) communication transmission and reception within a narrow area. The antenna assembly has a first planar antenna element including: (i) a radiating end portion extending in a first direction and electrically connectable to an antenna feed; and (ii) a radiating arm extending in a second direction opposite to the first direction. The antenna assembly has a second planar antenna element including: (i) a coupling arm extending in the second direction parallel to and spaced by a slit from the radiating arm of the first planar antenna element; and (ii) a coupling end portion extending in the first direction from the coupling arm and electrically connectable to an antenna ground.

According to a second aspect of the present disclosure, a communication device incorporates at least one antenna assembly. The communication device includes a support structure having a rectangular prismatic shape with a front side and back side that are larger than left, right, top, and bottom sides. A first antenna assembly of the at least one antenna assembly includes the first antenna assembly positioned on a first selected side of the left, right, top and bottom sides of the support structure having a first direction aligned with a longest dimension of a corresponding side of the support structure. In one or more embodiments, the communication device has a rolling display form factor by including a rolling display positioned on the front side, extending over a roller mechanism, and onto the back side of the support structure. In one or more embodiments, a second antenna assembly of the at least one antenna assembly is positioned on a second selected side opposite to the first selected side and orthogonal to the second selected top and bottom side. The second antenna assembly has a corresponding radiating end portion electrically connected to an antenna feed and a corresponding coupling end portion electrically connected to an antenna ground.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical, and other changes may be made without departing from the spirit or scope of the present disclosure. The following detailed description is, therefore, not to be taken in a limiting sense, and the scope of the present disclosure is defined by the appended claims and equivalents thereof. Within the descriptions of the different views of the figures, similar elements can be provided with similar names and reference numerals as those of the previous figure(s). The specific numerals assigned to the elements are provided solely to aid in the description and are not meant to imply any limitations (structural or functional or otherwise) on the described embodiment. It will be appreciated that for simplicity and clarity of illustration, elements illustrated in the figures have not necessarily been drawn to scale. For example, the dimensions of some of the elements are exaggerated relative to other elements.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that term is utilized.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention. The description of the illustrative embodiments can be read in conjunction with the accompanying figures. Embodiments incorporating teachings of the present disclosure are shown and described with respect to the figures presented herein.

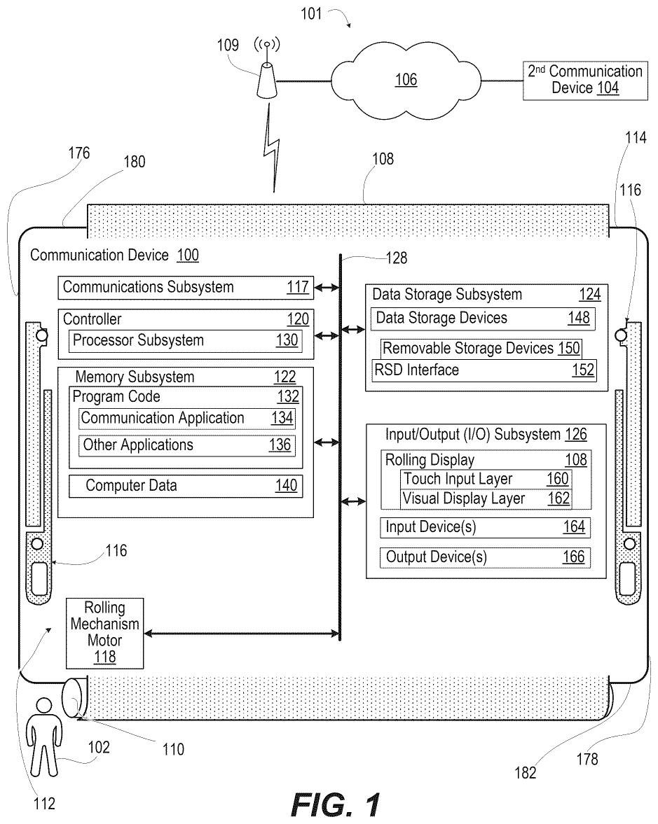

FIG. 1 presents a simplified functional block diagram of communication device 100 in which the features of the present disclosure are advantageously implemented to incorporate low band RF communications capabilities (i.e., LB antennas) into small and narrow edges of a small form factor. In one or more embodiments, communication device 100 operates as a handheld mobile user device in communication environment 101 for user 102. For clarity, communications environment 101 includes second communication device 104 that is communicatively coupled to communication network 106. Communication device 100 may wirelessly connect to node(s) 109 (e.g., cellular radio, wireless access) to establish a session with second communication device 104. Communication device 100 can be one of a host of different types of devices, including but not limited to, a mobile cellular phone, satellite phone, or smart phone, a laptop, a netbook, an ultra-book, a networked smartwatch, or networked sports/exercise watch, and/or a tablet computing device or similar device that can include wireless communication functionality. As a device supporting wireless communication, communication device 100 can be utilized as, and also be referred to as, a system, device, subscriber unit, subscriber station, mobile station (MS), mobile, mobile device, remote station, remote terminal, user terminal, terminal, user agent, user device, a session initiation protocol (SIP) phone, a wireless local loop (WLL) station, a personal digital assistant (PDA), computer workstation, a handheld device having wireless connection capability, a computing device, or other processing devices.

In the specific example of FIG. 1, communication device 100 has rolling display 108 positioned by rolling mechanism 110 to retract and extend across front side 112 of support structure 114. Communication device 100 includes at least one antenna assembly 116 that is configured for low band RF communications transmission and reception for communications subsystem 117. To support a relatively long wavelength requirement, antenna assembly 116 extends along either side of support structure 114 that is not blocked by rolling display 108 and rolling mechanism 110, including rolling mechanism motor 118.

In addition to communications subsystem 117, communication device 100 may include controller 120, memory subsystem 122, data storage subsystem 124 and input/output (I/O) subsystem 126. To enable management and control of the device components by controller 120, system interlink 128 communicatively connects controller 120 with communications subsystem 117, memory subsystem 122, data storage subsystem 124 and I/O subsystem 126. System interlink 128 represents internal components that facilitate internal communication by way of one or more shared or dedicated internal communication links, such as internal serial or parallel buses. As utilized herein, the term “communicatively coupled” means that information signals are transmissible through various interconnections, including wired and/or wireless links, between the components. The interconnections between the components can be direct interconnections that include conductive transmission media or may be indirect interconnections that include one or more intermediate electrical components. Although certain direct interconnections (i.e., system interlink 128) are illustrated in FIG. 1, it is to be understood that more, fewer, or different interconnections may be present in other embodiments.

Controller 120 includes processor subsystem 130, which includes one or more central processing units (CPUs) or data processors. Processor subsystem 130 can include one or more digital signal processors and graphics processing units (GPUs), etc. that can be integrated with data processor(s). Processor subsystem 130 can include other processors such as auxiliary processor(s) that may act as a low power consumption, always-on sensor hub for physical sensors. Controller 120 manages, and in some instances directly controls, the various functions and/or operations of communication device 100. These functions and/or operations include, but are not limited to including, application data processing, communication, navigation tasks, image processing, and signal processing. In one or more alternate embodiments, communication device 100 may use hardware component equivalents for application data processing and signal processing. For example, communication device 100 may use special purpose hardware, dedicated processors, general purpose computers, microprocessor-based computers, micro-controllers, optical computers, analog computers, dedicated processors and/or dedicated hard-wired logic.

Memory subsystem 122 stores program code 132 for execution by processor subsystem 130 to provide the functionality described herein. Program code 132 includes applications such as communications application 134 and other applications 136. In one or more embodiments, program code 132 may be integrated into a distinct chipset or hardware module as firmware that operates separately from executable program code. Portions of program code 132 may be incorporated into different hardware components that operate in a distributed or collaborative manner. Memory subsystem 122 further includes operating system (OS), firmware interface, such as basic input/output system (BIOS) or Uniform Extensible Firmware Interface (UEFI), and firmware, which also includes and may thus be considered as program code 132. Program code 132 may access, use, generate, modify, store, or communicate computer data 140. Computer data 140 may incorporate “data” that originated as raw, real-world “analog” information that consists of basic facts and figures. Computer data 140 includes different forms of data, such as numerical data, images, coding, notes, and financial data. Computer data 140 may originate at communication device 100 or be retrieved from a remote device via communications subsystem 117. Communication device 100 may store, modify, present, or transmit computer data 140. Computer data 140 may be organized in one of a number of different data structures. Common examples of computer data 140 include video, graphics, text, and images. Computer data 140 can also be in other forms of flat files, databases, and other data structures.

Data storage subsystem 124 of communication device 100 includes data storage device(s) 148. Controller 120 is communicatively connected, via system interlink 128, to data storage device(s) 148. Data storage subsystem 124 provides program code 132 and computer data 140 stored on nonvolatile storage that is accessible by controller 120. For example, data storage subsystem 124 can provide a selection of program code 132 and computer data 140. These applications can be loaded into memory subsystem 122 for execution/processing by controller 120. In one or more embodiments, data storage device(s) 148 can include hard disk drives (HDDs), optical disk drives, and/or solid-state drives (SSDs), etc. Data storage subsystem 124 of communication device 100 can include removable storage device(s) (RSD(s)) 150, which is received in RSD interface 152. Controller 120 is communicatively connected to RSD 150, via system interlink 128 and RSD interface 152. In one or more embodiments, RSD 150 is a non-transitory computer program product or computer readable storage device that provides program code and data, which may be processed by a processor associated with a user device such as communication device 100. Controller 120 can access data storage device(s) 148 or RSD 150 to provision communication device 100 with program code 132 and computer data 140.

I/O subsystem 126 includes rolling display 108 that includes touch input layer 160 and visual display layer 162. I/O subsystem 126 may include internal input devices 164 such as image capturing device(s), microphone, and touch input devices (e.g., screens, keys, or buttons). I/O subsystem 126 may include external input devices 164 such as physical buttons/actuators 165. I/O subsystem 126 may include output devices 166 such as other displays, lights, audio output devices, and vibratory or haptic output devices.

In one or more embodiments, controller 120, via communications subsystem 117, performs multiple types of cellular over-the-air (OTA) communications. In one or more embodiments, controller 120, via communications subsystem 117, may communicate via an OTA cellular connection with radio access networks (RANs). In an example, communication device 100, via communications subsystem 117, connects via RANs of a terrestrial network that is communicatively connected to a network server. In one or more embodiments, controller 120, via communications subsystem 117, communicates via a wireless local area network (WLAN) link using one or more IEEE 802.11 WLAN protocols with an access point. In one or more embodiments, controller 120, via communications subsystem 117, performs other types of wireless communication, such as by using a Bluetooth connection or other personal access network (PAN) connection. In an example, a user may wear a health monitoring device such as a smartwatch that is communicatively coupled to communication device 100 via a wireless connection. In one or more embodiments, communications subsystem 117 includes a global positioning system (GPS) module that receives GPS broadcasts from GPS satellites to obtain geospatial location information, which enables communication device 100 to self-locate, among other features.

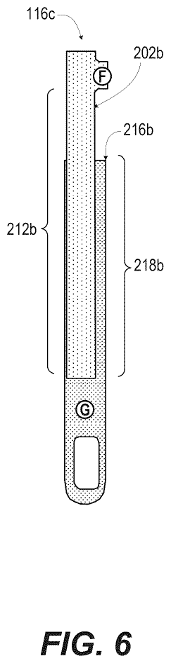

According to aspects of the present disclosure, communication device 100 includes support structure 114 having a rectangular prismatic shape with front side 112 and back side 174 (FIG. 6) that are larger than left side 176, right side 178, top side 180, and bottom side 182. At least one antenna assembly 116 is aligned with a longest dimension of a corresponding side of support structure 114, such as respectively at left side 176 and right side 178.

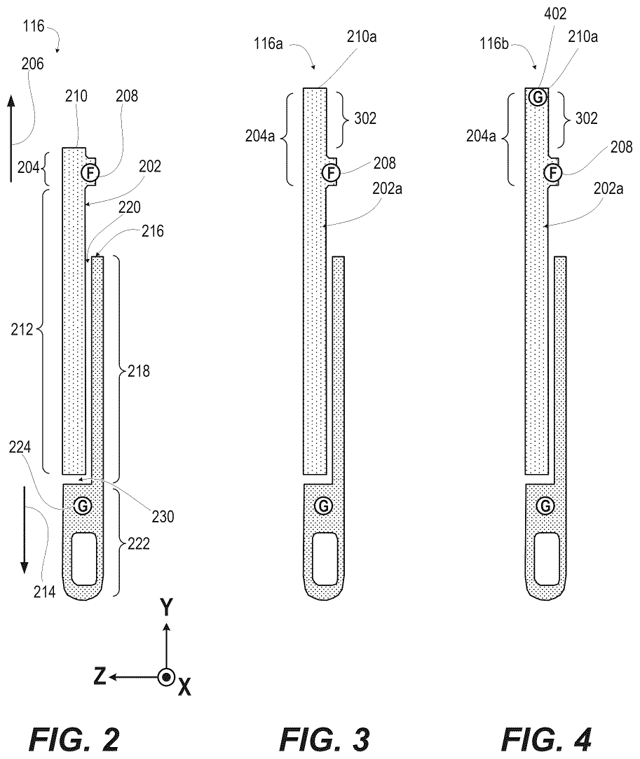

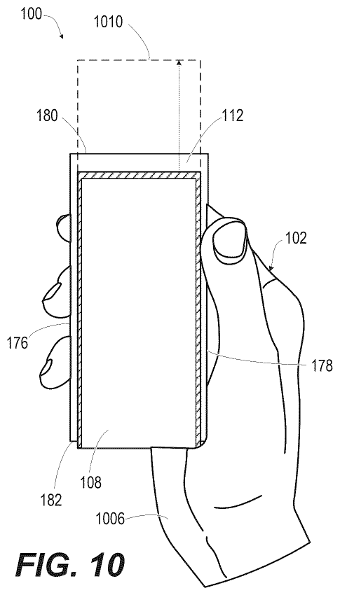

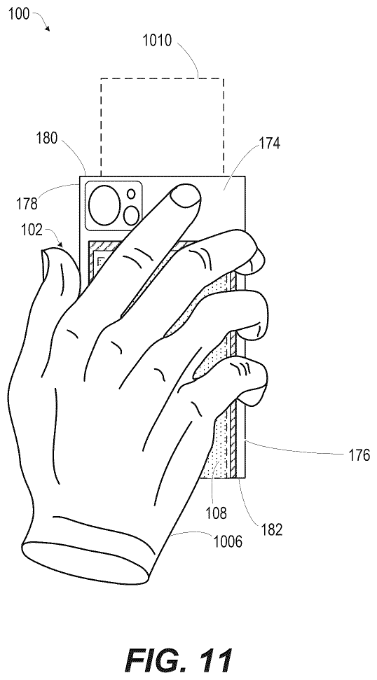

FIG. 2 illustrates antenna assembly 116 dimensioned for low band (LB) radio frequency (RF) communications. Antenna assembly 116 has first planar antenna element 202 including radiating end portion 204 extending in a first direction as indicated by arrow 206 and electrically connectable to antenna feed 208. In one or more embodiments, radiating end portion 204 has a feed location that is proximate to terminal edge 210 of first planar antenna element 202 in the first direction. First planar antenna element 202 includes radiating arm 212 extending in a second direction as indicated by arrow 214 opposite to the first direction. Antenna assembly 116 has second planar antenna element 216 including coupling arm 218 extending in the second direction parallel to and spaced by slit 220 from radiating arm 212 of first planar antenna element 202. Second planar antenna element 216 includes coupling end portion 222 extending in the first direction from coupling arm 218 and electrically connectable to antenna ground 224. In one or more embodiments, radiating arm 212 is juxtaposed to, in planar alignment with, and separated by slit 220 from coupling arm 218. Radiating arm 212 of first planar antenna element 202 and coupling arm 218 of second planar antenna element 216 are dimensioned for low band radio frequency (RF) communications. In one or more embodiments, radiating arm 212 of first planar antenna element and coupling arm 218 of second planar antenna element 216 are further dimensioned for ultra-low band (ULB) RF communications. Slit 220 is aligned longitudinally in the Y-direction and terminating at gap 230 that is aligned orthogonally in the Z-direction. As discussed below, slit 220 and gap 230 are dimensioned to mitigate blocking by one or two fingers as described below with regard to FIGS. 10-11.

FIG. 3 illustrates example antenna assembly 116a dimensioned as described for antenna assembly 116 (FIG. 2) for LB/ULB communications with radiating end portion 204a further including short arm 302. Short arm 302 is dimensioned for one or more of medium band (MB), high band (HB), and ultra-high band (UHB) communications. Radiating end portion 204a has a feed location. Short arm 302 extends in the first direction from the feed location. Short arm 302 is shorter than radiating arm 212 for higher RF band communications than LB/ULB. Terminal edge 210a of first planar antenna element 202a is electrically open and uncoupled.

FIG. 4 illustrates example antenna assembly 116b that is identical to antenna assembly 116a (FIG. 3) with the exception of terminal edge 210a of short arm 302 being electrically coupled to second ground 402. Grounding of first planar antenna element 202b proximate to antenna feed improves LB tuning.

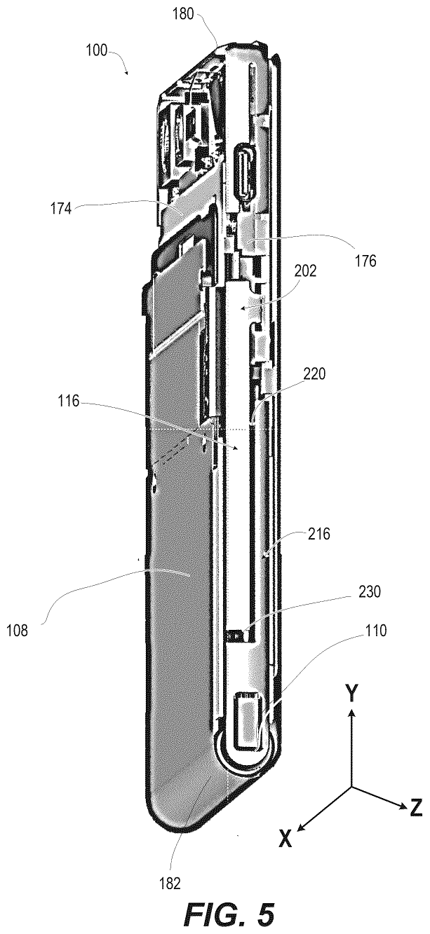

FIG. 5 is a three-dimensional view of example communication device 100 that includes rolling mechanism 110 and that incorporates antenna assembly 116 on a lateral side, such as left side 176. Rolling display 108 is partially rolled onto back side 174 by rolling mechanism 110. The planar alignment provides for a thinner thickness of antenna assembly 116 in the X-direction. Antenna assembly 116a (FIG. 3) and antenna assembly 116b (FIG. 4) may be similarly incorporated in communication device 100. Radiating arm 212 of first planar antenna element 202 and coupling arm 218 of second planar antenna element 216 are spaced apart in part by slit 220 that is aligned longitudinally in the Y-direction. The open end of radiating arm 212 is spaced apart from coupling end portion 222 by gap 230 in the Z-direction. Slit 220 and gap 230 configure antenna assembly 116 for LB communications.

FIG. 6 illustrates example antenna assembly 116c that is similar to antenna assembly 116 (FIG. 2) except first and second planar antenna elements 202b and 216b are configured so that radiating arm 212b is positioned laterally in parallel planar alignment with coupling arm 218b that is positioned medially. This stacked arrangement may allow for a narrower implementation in the planes of first and second planar antenna elements 202b and 216b. As described below regarding FIGS. 6-9, the stacked arrangement does increase a thickness of antenna assembly 116c orthogonally to the planes of first and second planar antenna elements 202b and 216b as compared to a flat aligned versions of antenna assembly 116 (FIG. 2), 116a (FIG. 3), and 116b (FIG. 4). However, the stacked arrangement of first and second planar antenna elements 202b and 216b may enable a narrower dimension of antenna assembly 116c, and thus use in a thinner communication device.

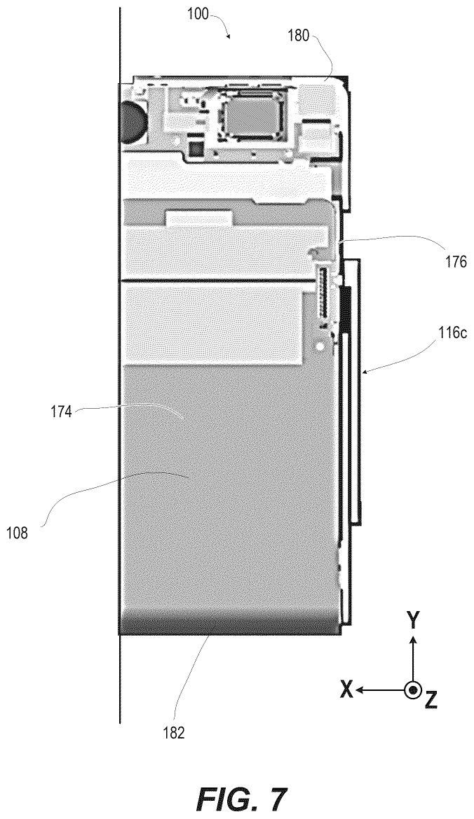

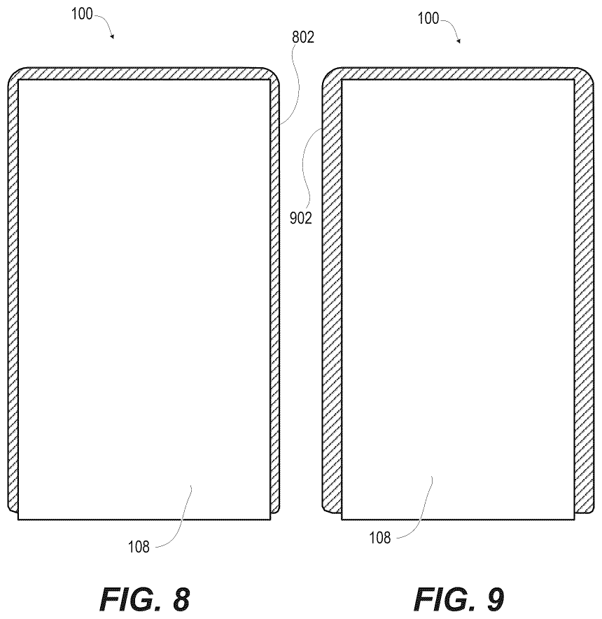

FIG. 7 illustrates a cutaway front right side of example communication device 100 having antenna assembly 116c (FIG. 5). The stacked arrangement creates a thicker antenna assembly 116c in the X-direction. FIG. 8 illustrates a front view of communication device 100 with rolling display 108 surrounded by a thin edge portion 802 that can enclose any of antenna assembly 116 (of FIG. 2, FIG. 3, and/or FIG. 4. FIG. 9 illustrates a front view of communication device 100 with rolling display 108 surrounded by a thick edge portion 902 that can enclose antenna assembly 116c (FIG. 5).

FIG. 10 illustrates a front view of example communication device 100 being gripped on left and right sides 176 and 178 by right hand 1006 of user 102. Rolling display 108 is in a retracted position on front side 112 of communication device 100 with dashed line annotation 1010 representing rolling display 108 in an extended position. FIG. 11 illustrates a back view of example communication device 100 of FIG. 10 being gripped on left and right sides 176 and 178 by right hand 1006 of user 102 that is over back side 182 of communication device 100. With reference to FIGS. 10-11, front side 112 (FIG. 1) and back side 174 of communication device 100 are larger in area than left side 176, right side 178, top side 180 and bottom side 182. Only left side 176 and right side 178 are candidate locations for a LB antenna due to rolling display 108 blocking the other sides (112, 174, 180, 182). The upward extension of rolling display 108 is an example implementation or a rolling display. In an example, communication device 100 may be held in any orientation with the extension direction corresponding to the orientation. In another example, a communication device may extend on both opposite sides. In an additional example, the handheld form factor may include a folding form factor in addition to rolling. Communication device 100 may be palm sized when retracted or can be larger, such as with a tablet form factor. Generally known communication devices that have fixed displays tend to have antennas, especially LB antennas, near the four corners of the communication device to provide for spatial diversity and multiple input multiple output (MIMO) communications. In one or more embodiments, having antenna assemblies 116 (block FIG. 1) opposite lateral sides are closer together than opposite top and bottom corners. Given the long wavelength of LB/ULB, the pair of antenna assemblies 116 (block FIG. 1) create less interference to each other than conventional paired antenna assemblies on opposite top and bottom corners.

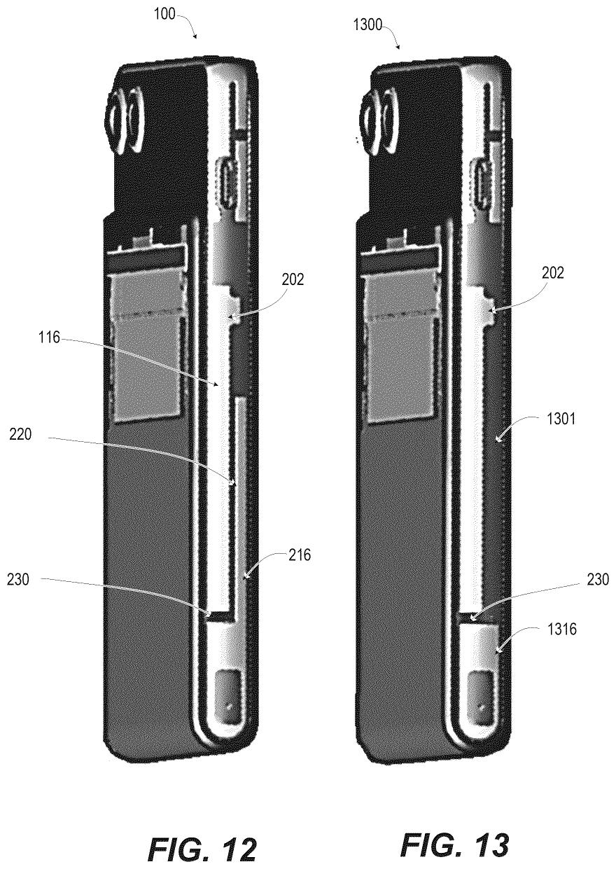

FIG. 12 is a three-dimensional view of communication device 100 with antenna assembly 116 for simulated antenna performance comparison. FIG. 13 is a three-dimensional view of communication device 1300 having antenna assembly 1301 that only has first planar antenna elements 202 in line with stub second planar antenna assembly 1316 having no coupling arm, thus providing a more conventional LB solution. The relatively short gap 230 with no longitudinal slit makes the antenna more susceptible to complete blocking by head or finger. By contrast, the length of coupling provided by having slit 220 in addition to short gap 230 ensures that communication device 100 (FIG. 12) will have available coupling portions for effective antenna performance.

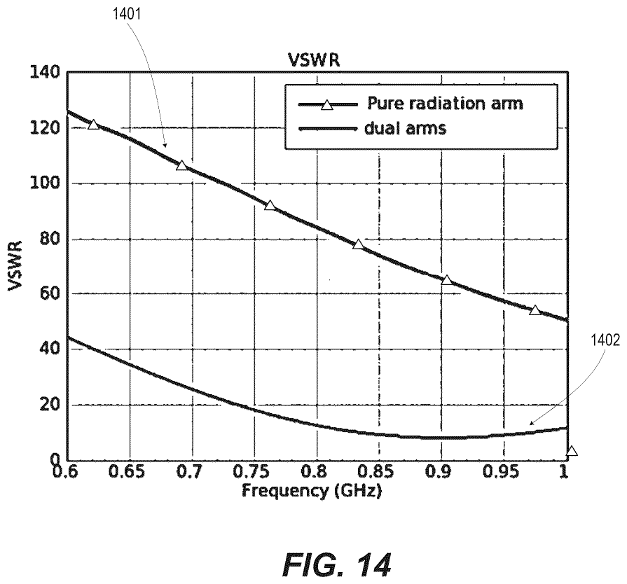

FIG. 14. depicts graphical plots 1401 and 1402 of voltage standing wave ratio (VSWR) as a function of frequency respectively for conventional antenna assembly 1316 (FIG. 13) and antenna assembly 116 (FIG. 12). Graphical plot 1401 is too high for the antenna to be able to be matched for efficient transfer of a signal and would not be suitable for LB communications. In an example, simulation indicates VSWR of 120 to 46 VSWR corresponding to a frequency of 0.6 GHz to 1 GHz. By contrast, graphical plot 1402 is entirely below 45 VSWR for frequencies between 0.6 GHz to 1 GHz, providing required antenna efficiency.

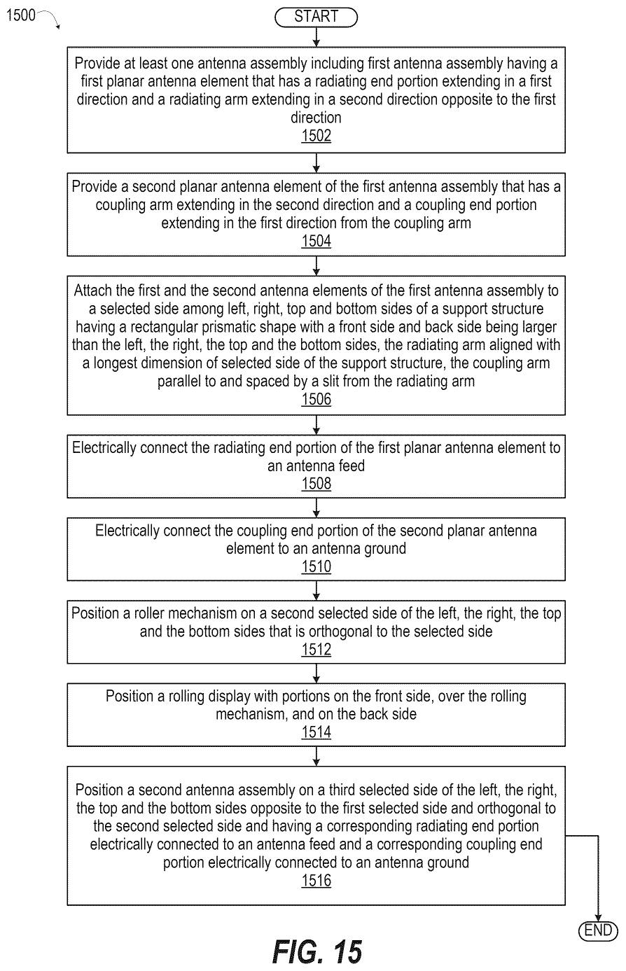

FIG. 15 is a flow diagram presenting method 1500 for making communication device having an antenna assembly configured for low band (LB) communication and positioned on a narrow side of a support structure. The description of method 1500 is provided with general reference to the specific components illustrated within the preceding FIGS. 1-12. Specific components referenced in method 1500 (FIG. 15) may be identical or similar to components of the same name used in describing preceding FIGS. 1-12.

With reference to FIG. 15, method 1500 includes providing at least one antenna assembly including first antenna assembly having a first planar antenna element that has a radiating end portion extending in a first direction and a radiating arm extending in a second direction opposite to the first direction (block 1502). Method 1500 includes providing a second planar antenna element of the first antenna assembly that has a coupling arm extending in the second direction and a coupling end portion extending in the first direction from the coupling arm (block 1504). Method 1500 includes attaching the first and the second planar antenna elements of the first antenna assembly to a selected side among left, right, top and bottom sides of a support structure having a rectangular prismatic shape with a front side and back side being larger than the left, the right, the top, and the bottom sides, the radiating arm aligned with a longest dimension of selected side of the support structure, the coupling arm parallel to and spaced by a slit from the radiating arm (block 1506). Method 1500 includes electrically connecting the radiating end portion of the first planar antenna element to an antenna feed (block 1508). Method 1500 includes electrically connecting the coupling end portion of the second planar antenna element to an antenna ground (block 1510). Method 1500 includes positioning a roller mechanism on a second selected side of the left, the right, the top and the bottom sides that is orthogonal to the selected side (block 1512).

Method 1500 includes positioning a rolling display with portions on the front side, over the rolling mechanism, and on the back side (block 1514). Method 1500 includes positioning a second antenna assembly on a third selected side of the left, the right, the top and the bottom sides opposite to the first selected side and orthogonal to the second selected side and having a corresponding radiating end portion electrically connected to an antenna feed and a corresponding coupling end portion electrically connected to an antenna ground (block 1516). Then method 1500 ends.

In one or more embodiments, the radiating end portion of each of the at least one antenna assembly has a feed location that is proximate to a terminal edge of the first planar antenna element in the first direction. In one or more embodiments, the first planar antenna element and the second planar antenna element are dimensioned for low band radio frequency (RF) communications. The radiating end portion of the first planar antenna element has a feed location and includes a short arm extending in the first direction from the feed location. The short arm is shorter than the radiating arm for higher RF band communications. In one or more particular embodiments, method 1500 includes electrically connecting a terminal end of the short arm to an antenna ground.

In one or more embodiments, the radiating arm is juxtaposed to, in planar alignment with, and separated by the slit from the coupling arm. In one or more alternate embodiments, the radiating arm is positioned laterally in parallel planar alignment with the coupling arm that is positioned medially.

Accordingly, the present disclosure provides an antenna assembly that supports low band (LB) radio frequency (RF) communication transmission and reception within a narrow area. In an example, a pair of the antenna assemblies can fit within the narrow left and right sides of a handheld communication device having rolling display. By having a slit between antenna elements of the antenna assembly, gripping of the left and right sides does not wholly block the electromagnetic coupling between antenna elements, enabling effective transmission and reception. Embodiments of the antenna assembly include a small arm for higher communication band support.

Aspects of the present innovation are described above with reference to flowchart illustrations and/or block diagrams of methods, apparatus (systems) and computer program products according to embodiments of the innovation. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

As will be appreciated by one skilled in the art, embodiments of the present innovation may be embodied as a system, device, and/or method. Accordingly, embodiments of the present innovation may take the form of an entirely hardware embodiment or an embodiment combining software and hardware embodiments that may all generally be referred to herein as a “circuit,” “module” or “system.”

While the innovation has been described with reference to exemplary embodiments, it will be understood by those skilled in the art that various changes may be made, and equivalents may be substituted for elements thereof without departing from the scope of the innovation. In addition, many modifications may be made to adapt a particular system, device, or component thereof to the teachings of the innovation without departing from the essential scope thereof. Therefore, it is intended that the innovation not be limited to the particular embodiments disclosed for carrying out this innovation, but that the innovation will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the innovation. As used herein, the singular forms “a”, “an” and “the” are intended to include the plural forms as well, unless the context clearly indicates otherwise. It will be further understood that the terms “comprise” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present innovation has been presented for purposes of illustration and description but is not intended to be exhaustive or limited to the innovation in the form disclosed. Many modifications and variations will be apparent to those of ordinary skill in the art without departing from the scope and spirit of the innovation. The embodiments were chosen and described in order to best explain the principles of the innovation and the practical application, and to enable others of ordinary skill in the art to understand the innovation for various embodiments with various modifications as are suited to the particular use contemplated.

What is claimed is:

1. An antenna assembly comprising:
a first planar antenna element comprising:
a radiating end portion extending in a first direction and electrically connectable to an antenna feed; and
a radiating arm extending in a second direction opposite to the first direction; and
a second planar antenna element comprising:
a coupling arm extending in the second direction parallel to and spaced by a slit from the radiating arm of the first planar antenna element; and
a coupling end portion extending in the first direction from the coupling arm and electrically connectable to an antenna ground.

2. The antenna assembly of claim 1, wherein the radiating end portion has a feed location that is proximate to a terminal edge of the first planar antenna element in the first direction.

3. The antenna assembly of claim 1, wherein:
the first planar antenna element and the second planar antenna element are dimensioned for low band radio frequency (RF) communications; and
the radiating end portion of the first planar antenna element has a feed location and comprises a short arm extending in the first direction from the feed location, the short arm being shorter than the radiating arm for higher RF band communications.

4. The antenna assembly of claim 3, wherein the short arm comprises a terminal end that is electrically connectable to an antenna ground.

5. The antenna assembly of claim 1, wherein the radiating arm is juxtaposed to, in planar alignment with, and separated by the slit from the coupling arm.

6. The antenna assembly of claim 1, wherein the radiating arm is positioned laterally in parallel planar alignment with the coupling arm that is positioned medially.

7. A communication device comprising:
a support structure having a rectangular prismatic shape with a front side and back side that are larger than left, right, top, and bottom sides; and
at least one antenna assembly comprising a first antenna assembly positioned on a first selected side of the left, right, top and bottom sides of the support structure and comprising:
a first planar antenna element comprising:
a radiating end portion extending in a first direction and electrically connectable to an antenna feed; and
a radiating arm extending in a second direction opposite to the first direction aligned with a longest dimension of a corresponding side of the support structure; and
a second planar antenna element comprising:
a coupling arm extending in the second direction parallel to and spaced by a slit from the radiating arm; and
a coupling end portion extending in the second direction from the coupling arm and electrically connectable to an antenna ground.

8. The communication device of claim 7, further comprising:
a roller mechanism positioned on one of a second selected side of the left, the right, the top and the bottom sides orthogonal to the first selected side;
a rolling display positioned on the front side, extending over the roller mechanism, and onto the back side of the support structure; and
a second antenna assembly positioned on a second selected side opposite to the first selected side and orthogonal to the second selected top and bottom side and having a corresponding radiating end portion electrically connected to an antenna feed and a corresponding coupling end portion electrically connected to an antenna ground.

9. The communication device of claim 7, wherein the radiating end portion of each of the at least one antenna assembly has a feed location that is proximate to a terminal edge of the first planar antenna element in the first direction.

10. The communication device of claim 7, wherein:
the first planar antenna element and the second planar antenna element are dimensioned for low band radio frequency (RF) communications; and
the radiating end portion of the first planar antenna element has a feed location and comprises a short arm extending in the first direction from the feed location, the short arm being shorter than the radiating arm for higher RF band communications.

11. The communication device of claim 10, wherein the short arm comprises a terminal end that is electrically connectable to an antenna ground.

12. The communication device of claim 10, wherein the radiating arm is juxtaposed to, in planar alignment with, and separated by the slit from the coupling arm.

13. The communication device of claim 10, wherein the radiating arm is positioned laterally in parallel planar alignment with the coupling arm that is positioned medially.

14. A method comprising:
providing at least one antenna assembly comprising a first antenna assembly comprising a first planar antenna element comprising a radiating end portion extending in a first direction and a radiating arm extending in a second direction opposite to the first direction;
providing a second planar antenna element of the first antenna assembly comprising a coupling arm extending in the second direction and a coupling end portion extending in the first direction from the coupling arm;
attaching the first and the second planar antenna elements of the first antenna assembly to a selected side among left, right, top and bottom sides of a support structure having a rectangular prismatic shape with a front side and back side being larger than the left, the right, the top and the bottom sides, the radiating arm aligned with a longest dimension of selected side of the support structure, the coupling arm parallel to and spaced by a slit from the radiating arm;
electrically connecting the radiating end portion of the first planar antenna element to an antenna feed; and
electrically connecting the coupling end portion of the second planar antenna element to an antenna ground.

15. The method of claim 14, further comprising:
positioning a roller mechanism on a second selected side of the left, the right, the top and the bottom sides that is orthogonal to the selected side;
positioning a rolling display on the front side, the rolling mechanism, and the back side; and
positioning a second antenna assembly on a third selected side of the left, the right, the top and the bottom sides opposite to the first selected side and orthogonal to the second selected side and having a corresponding radiating end portion electrically connected to an antenna feed and a corresponding coupling end portion electrically connected to an antenna ground.

16. The method of claim 14, wherein the radiating end portion of each of the at least one antenna assembly has a feed location that is proximate to a terminal edge of the first planar antenna element in the first direction.

17. The method of claim 14, wherein:
the first planar antenna element and the second planar antenna element are dimensioned for low band radio frequency (RF) communications; and
the radiating end portion of the first planar antenna element has a feed location and comprises a short arm extending in the first direction from the feed location, the short arm being shorter than the radiating arm for higher RF band communications.

18. The method of claim 17, further comprising electrically connecting a terminal end of the short arm to an antenna ground.

19. The method of claim 17, wherein the radiating arm is juxtaposed to, in planar alignment with, and separated by the slit from the coupling arm.

20. The method of claim 17, wherein the radiating arm is positioned laterally in parallel planar alignment with the coupling arm that is positioned medially.
